(19) United States
(12) Patent Application Publication
(10) Pub. No.: US 2024/0424609 A1
(43) Pub. Date: Dec. 26, 2024

(54) METHOD OF PROCESSING WORKPIECE

(71) Applicant: DISCO CORPORATION, Tokyo (JP)

(72) Inventor: Yuki IKEDA, Tokyo (JP)

(21) Appl. No.: 18/678,742

(22) Filed: May 30, 2024

(30) Foreign Application Priority Data
Jun. 22, 2023 (JP) 2023-102745

(51) Int. Cl. B23K 26/38; B23K 26/364; B23K 26/70

(52) U.S. Cl. CPC B23K 26/38; B23K 26/364; B23K 26/70

(57) ABSTRACT

A method of processing a workpiece includes a first processing step of applying the laser beam to the workpiece along a plurality of first projected dicing lines to divide the workpiece into a plurality of strips, and after the first processing step, a second processing step of applying the laser beam to the workpiece along a plurality of second projected dicing lines to divide the workpiece into a plurality of chips. The first processing step includes applying the laser beam along each of the first projected dicing lines from one end to another end thereof. The second processing step includes repeating a cycle of applying the laser beam along one of the second projected dicing lines from one end to another end thereof and thereafter applying the laser beam along a next one of the second projected dicing lines from the other end to the one end thereof.

### BACKGROUND OF THE INVENTION

### Field of the Invention

The present invention relates to a method of processing a workpiece having established thereon first projected dicing lines extending in a first direction and second projected dicing lines extending in a second direction.

### Description of the Related Art

There has been known a laser processing apparatus that applies a laser beam to a workpiece to divide the workpiece into segments while moving the workpiece back and forth in directions parallel to projected dicing lines on the workpiece relatively to the laser beam for thereby shortening a period of time in which to process the workpiece with the laser beam (see, for example, JP 2016-132017A).

For segmenting a workpiece into chips with the laser processing apparatus disclosed in JP 2016-132017A, it has been customary to divide the workpiece along first projected dicing lines established on the workpiece that extend in a first direction into a plurality of strips and then divide the strips along second projected dicing lines established on the workpiece that extend in a second direction.

### SUMMARY OF THE INVENTION

When the workpiece is divided along the first projected dicing lines into the strips, the strips may tend to shift in position along the first direction. This phenomenon manifests itself partly if the width of the strips, i.e., an index size, is of a small value of 0.5 mm or less.

For example, if the workpiece has a plurality of devices constructed in respective areas demarcated by the projected dicing lines, then when the strips divided from the workpiece are shifted in position, the second projected dicing lines do not line up, possibly letting the laser beam applied to the strips along the second direction be applied to the devices and damage the devices.

It is therefore an object of the present invention to provide a method of processing a workpiece while minimizing damage caused to devices on the workpiece.

In accordance with an aspect of the present invention, there is provided a method of processing a workpiece to divide the workpiece into a plurality of chips along a grid of projected dicing lines established thereon that include a plurality of first projected dicing lines extending in a first direction and a plurality of second projected dicing lines extending in a second direction that traverses the first direction. The method includes a first processing step of applying a laser beam to the workpiece along the first projected dicing lines to divide the workpiece into a plurality of strips, and after the first processing step, a second processing step of applying the laser beam to the workpiece along the second projected dicing lines to divide the workpiece into a plurality of chips. The first processing step includes applying the laser beam to the workpiece along the first projected dicing lines from one ends to other ends of the first projected dicing lines, and repeating a cycle of applying the laser beam to the workpiece along one of the second projected dicing lines from one end to other end of the one of the second projected dicing lines and thereafter applying the laser beam to the workpiece along a next one of the second projected dicing lines from the other end to the one end of the next one of the second projected dicing lines.

Preferably, the method further includes, before the first processing step, a laser-processed groove forming step of applying the laser beam to the workpiece along the first projected dicing lines to form first laser-processed grooves in the workpiece along the first projected dicing lines and thereafter applying the laser beam to the workpiece along the second projected dicing lines to form second laser-processed grooves in the workpiece along the second projected dicing lines. The laser-processed groove forming step includes repeating a cycle of applying the laser beam to the workpiece along one of the first projected dicing lines or the second projected dicing lines from one end to other end of the one of the first projected dicing lines or the second projected dicing lines and thereafter applying the laser beam to the workpiece along a next one of the first projected dicing lines or the second projected dicing lines from the other end to the one end of the next one of the first projected dicing lines or the second projected dicing lines.

In accordance with another aspect of the present invention, there is provided a method of processing a workpiece to divide the workpiece into a plurality of chips along a grid of projected dicing lines established thereon that include a plurality of first projected dicing lines extending in a first direction and a plurality of second projected dicing lines extending in a second direction that traverses the first direction. The method includes a first processing step of applying a laser beam to the workpiece along the first projected dicing lines to divide the workpiece into a plurality of strips, and after the first processing step, a second processing step of applying the laser beam to the workpiece along the second projected dicing lines to divide the workpiece into a plurality of chips The first processing step includes repeating a cycle of applying the laser beam to the workpiece along one of the first projected dicing lines from one end to other end of the one of the first projected dicing lines, applying the laser beam to the workpiece along the one of the first projected dicing lines from the other end to the one end of the one of the first projected dicing lines that has been irradiated with the laser beam, and applying the laser beam to the workpiece along a next one of the first projected dicing lines.

Preferably, the method further includes, before the first processing step, a tape affixing step of affixing a vinyl chloride tape to the workpiece.

The present invention is advantageous in that the method can process a workpiece while minimizing damage caused to devices on the workpiece.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view schematically illustrating a workpiece to be processed by a method of processing a workpiece, also referred to as a “workpiece processing method,” according to a first embodiment of the present invention;

FIG. 2 is a flowchart of the sequence of the workpiece processing method according to the first embodiment;

FIG. 3 is a perspective view schematically illustrating the workpiece after a tape affixing step of the workpiece processing method illustrated in FIG. 2;

FIG. 4 is a perspective view schematically illustrating a structural example of a laser processing apparatus that carries out an alignment step, a first processing step, and a second processing step of the workpiece processing method illustrated in FIG. 2;

FIG. 5 is a side elevational view, partly in cross section, schematically illustrating the alignment step of the workpiece processing method illustrated in FIG. 2;

FIG. 6 is a side elevational view, partly in cross section, schematically illustrating the first processing step and the second processing step of workpiece processing method illustrated in FIG. 2;

FIG. 7 is a plan view schematically illustrating a direction in which a laser beam is moved relatively to the workpiece in the first processing step of workpiece processing method illustrated in FIG. 2;

FIG. 8 is a plan view schematically illustrating the workpiece after the first processing step of the workpiece processing method illustrated in FIG. 2;

FIG. 9 is a plan view schematically illustrating the workpiece before the laser beam is applied thereto in the second processing step of the workpiece processing method illustrated in FIG. 2;

FIG. 10 is a plan view schematically illustrating directions in which the laser beam is moved relatively to the workpiece in the second processing step of the workpiece processing method illustrated in FIG. 2;

FIG. 11 is a flowchart of the sequence of a method of processing a workpiece according to a second embodiment of the present invention;

FIG. 12 is a plan view schematically illustrating directions in which a laser beam moves relatively to first projected dicing lines on a workpiece in a laser-processed groove forming step of the workpiece processing method illustrated in FIG. 11;

FIG. 13 is a plan view schematically illustrating directions in which the laser beam moves relatively to second projected dicing lines on the workpiece in the laser-processed groove forming step of the workpiece processing method illustrated in FIG. 11;

FIG. 14 is a plan view schematically illustrating a direction in which the laser beam moves relatively to the workpiece in a first processing step of the workpiece processing method illustrated in FIG. 11;

FIG. 15 is a plan view schematically illustrating directions in which the laser beam moves relatively to the workpiece in a second processing step of the workpiece processing method illustrated in FIG. 11;

FIG. 16 is a plan view schematically illustrating directions in which a laser beam moves relatively to first projected dicing lines on a workpiece in a first processing step of a method of processing a workpiece according to a third embodiment of the present invention; and

FIG. 17 is a plan view schematically illustrating directions in which the laser beam moves relatively to second projected dicing lines on the workpiece in a second processing step of the workpiece processing method according to the third embodiment.

### DETAILED DESCRIPTION OF THE PREFERRED EMBODIMENTS

Preferred embodiments of the present invention will be described in detail hereinbelow with reference to the accompanying drawings. The present invention is not limited to the details of the embodiments described below. The components described below cover those which could easily be anticipated by those skilled in the art and those which are essentially identical to those described below. Furthermore, the arrangements described below can be combined in appropriate manners. Various omissions, replacements, or changes of the arrangements may be made without departing from the scope of the present invention. In the description below, those components that are identical to each other are denoted by identical reference characters. Identical or corresponding parts are denoted by identical or corresponding reference characters throughout views.

### First Embodiment

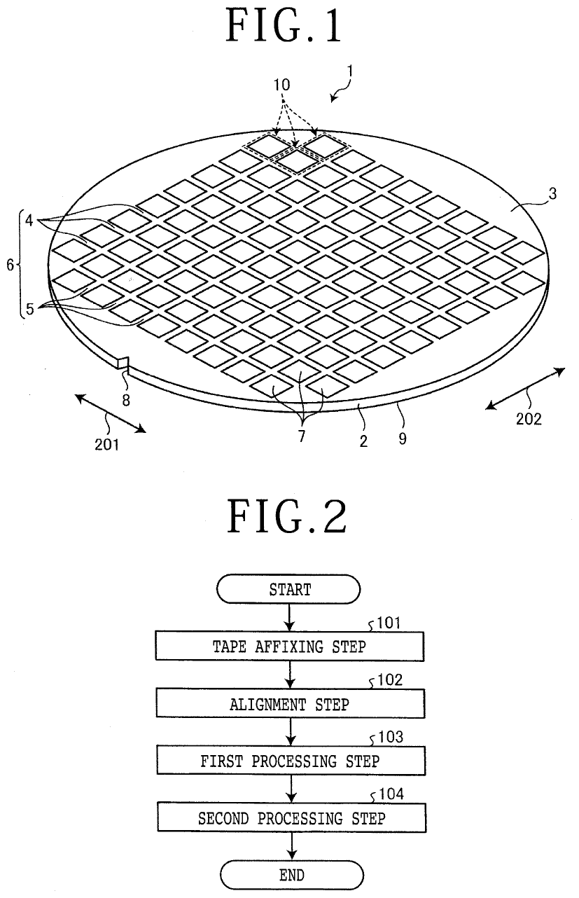

A method of processing a workpiece according to a first embodiment of the present invention will be described below with reference to the drawings. FIG. 1 schematically illustrates, in perspective, a workpiece to be processed by the workpiece processing method according to the first embodiment. FIG. 2 is a flowchart of the sequence of the workpiece processing method according to the first embodiment.

The workpiece processing method according to the present embodiment refers to a method of processing a workpiece 1 illustrated in FIG. 1. The workpiece 1 represents a wafer shaped as a circular plate such as a semiconductor wafer or an optical device wafer, which is of a circular shape, including a substrate 2 made of silicon (Si), gallium arsenide (GaAs), silicon carbide (SiC), or sapphire, for example.

The workpiece 1 has a plurality of projected dicing lines 6 established on a face side 3 of the substrate 2 that include a plurality of first projected dicing lines 4 extending in straight first directions 201 and a plurality of second projected dicing lines 5 extending in straight second directions 202 that traverse the first directions 201, e.g., that extend perpendicularly across the first directions 201 according to the present embodiment. The workpiece 1 includes a plurality of devices 7 constructed in respective areas demarcated on the face side 3 by the first and second projected dicing lines 4 and 5. Each of the devices 7 may be an integrated circuit (IC), a large-scale-integration (LSI) circuit, an image sensor such as a charge-coupled device (CCD) or a complementary metal oxide semiconductor (CMOS), an optical device such as a light-emitting device (LED), a microelectromechanical system (MEMS), or a semiconductor memory or a semiconductor storage device, for example.

According to the present embodiment, the workpiece 1 is an optical device wafer with LEDs as the devices 7. According to the present embodiment, furthermore, the workpiece 1 has a notch 8 defined as an irregularly shaped region in an outer edge thereof for indicating crystal orientations of the substrate 2.

The workpiece 1 will be divided into smaller individual chips 10 along the first projected dicing lines 4. Each of the chips 10 includes a portion of the substrate 2 and one of the devices 7. According to the first embodiment, each of the chips 10 is of a square (rectangular) shape having a size of 0.5 mm×0.5 mm. According to the present invention, the workpiece 1 is not limited to a circular wafer and may be any of various rectangular workpieces including a rectangular package substrate having a plurality of resin-encapsulated devices, a ceramic plate, and a glass plate, for example.

The workpiece processing method according to the first embodiment refers to a method of dividing the workpiece 1 into the chips 10 along the first and second projected dicing lines 4 and 5 established on the face side 3 of the workpiece 1. As illustrated in FIG. 2, the workpiece processing method according to the first embodiment includes tape affixing step 101, alignment step 102, first processing step 103, and second processing step 104.

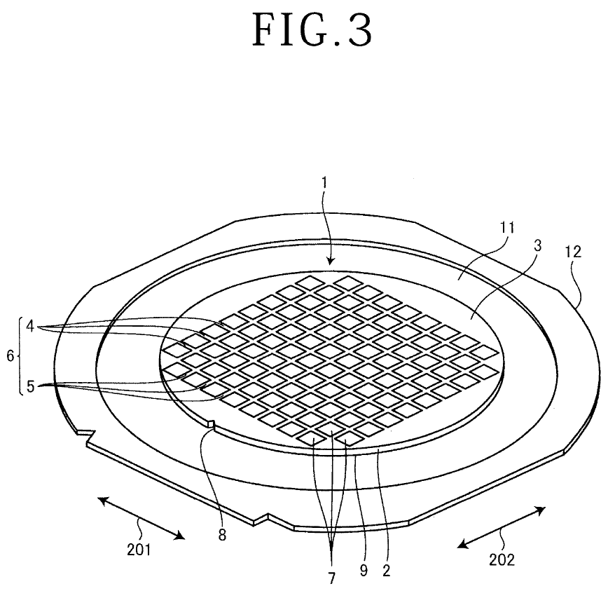

FIG. 3 schematically illustrates, in perspective, the workpiece 1 after tape affixing step 101 of the workpiece processing method illustrated in FIG. 2. As illustrated in FIG. 3, tape affixing step 101 is a step of affixing a vinyl chloride tape 11 to the workpiece 1 in preparation for first processing step 103.

According to the first embodiment, as illustrated in FIG. 3, the vinyl chloride tape 11 is shaped as a circular sheet that is larger in diameter than the workpiece 1 and that has an outer edge portion to which an annular frame 12 is attached. In tape affixing step 101, the vinyl chloride tape 11 has a central portion affixed to a reverse side 9, which is opposite the face side 3, of the substrate 2 of the workpiece 1, supporting the workpiece 1 thereon in an opening of the annular frame 12. The vinyl chloride tape 11 refers to an adhesive tape including a base made of non-adhesive and flexible polyvinyl chloride and a glue layer disposed on the base and made of adhesive and flexible resin. The glue layer is an adhesive tape in which the layer is attached to the annular frame 12 and the workpiece 1.

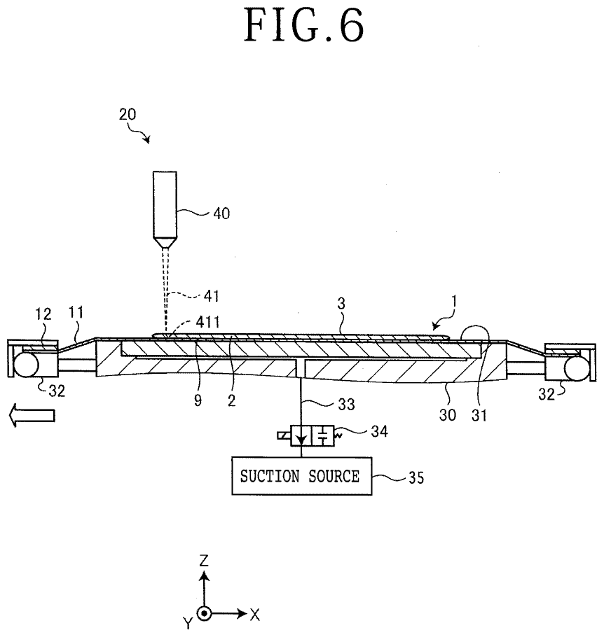

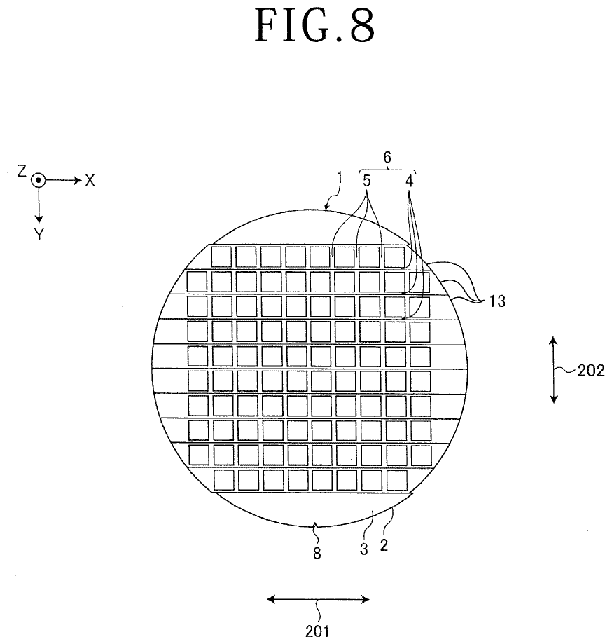

Since the base of the vinyl chloride tape 11 is made of polyvinyl chloride, the base that is normally affixed to the workpiece 1 has a lower melting point than an adhesive tape made of polyolefin or polyethylene terephthalate. When the workpiece 1 is cut into strips 13 (see FIG. 8) by a laser beam 41 (see FIG. 6) applied to the workpiece 1 in first processing step 103, as described later, the strips 13 are liable to shift back in position along the direction in which the laser beam 41 is moved relatively to the workpiece 1.

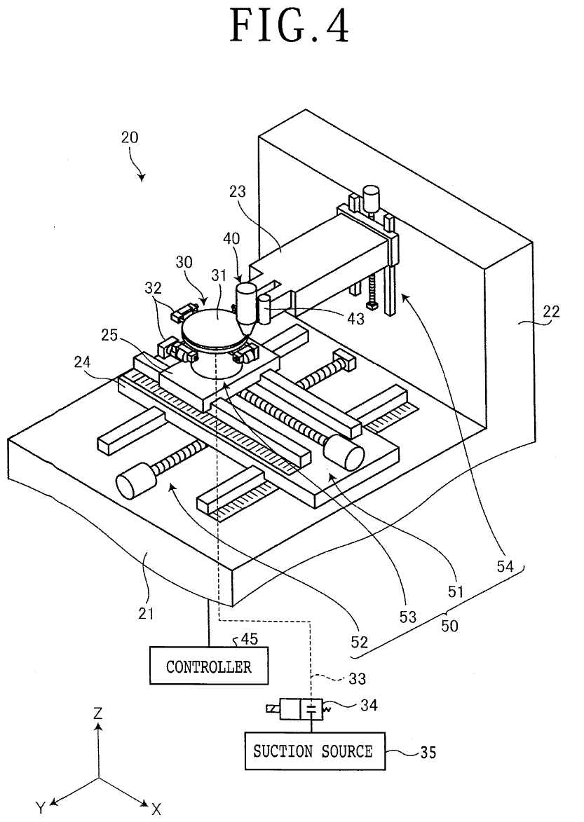

A laser processing apparatus for performing alignment step 102, first processing step 103, and second processing step 104 of the workpiece processing method illustrated in FIG. 2 will be described below. FIG. 4 schematically illustrates, in perspective, a structural example of the laser processing apparatus, denoted by 20. In FIG. 4 and some other figures, the laser processing apparatus 20 is illustrated in reference to a three-dimensional coordinate XYZ system having an X-axis represented by an arrow X, a Y-axis represented by an arrow Y, and a Z-axis represented by an arrow Z. The X-axis and the Y-axis extend horizontally and perpendicularly to each other, and the Z-axis extends vertically and perpendicularly to the X-axis and the Y-axis.

As illustrated in FIG. 4, the laser processing apparatus 20 refers to a processing apparatus for setting a focused spot 411 of the laser beam 41 on the face side 3 of the substrate 2 of the workpiece 1 and applying the laser beam 41, which is a pulsed laser beam having a wavelength absorbable by the substrate 2, to the face side 3 along the first and second projected dicing lines 4 and 5, thereby processing the workpiece 1 with the laser beam 41 by way of laser ablation. The laser processing apparatus 20 includes a holding table 30 for holding the workpiece 1 thereon, a laser beam applying unit 40, a moving unit assembly 50, an image capturing unit 43, and a controller 45.

The holding table 30 holds the workpiece 1 on a holding surface 31 thereof that extends parallel to horizontal directions, i.e., a horizontal plane defined by the X-axis and the Y-axis. The holding surface 31 is of a disk shape and is made of porous ceramic, for example. The holding surface 31 is fluidly connected to a suction source 35 via a suction channel 33 and an on/off valve 34. When the suction source 35 is actuated with the workpiece 1 placed on the holding surface 31, it generates and transmits a negative pressure through the on/off valve 34 and the suction channel 33 to the holding surface 31, holding the workpiece 1 under suction on the holding surface 31. A plurality of clamps 32 are disposed around the holding table 30 for gripping the annular frame 12 disposed on the vinyl chloride tape 11 around the workpiece 1 supported on the vinyl chloride tape 11 in the opening of the annular frame 12.

The holding table 30 can be turned by a turning unit 53 of the moving unit assembly 50 about a central axis that extends along the Z-axis perpendicularly to the holding surface 31. The holding table 30 is movable by an X-axis moving unit 51 of the moving unit assembly 50 in directions parallel to the X-axis, i.e., processing feed directions, and is also movable by a Y-axis moving unit 52 of the moving unit assembly 50 in directions parallel to the Y-axis i.e., indexing feed directions. The holding table 30 is further movable by the moving unit assembly 50 between a processing position below the laser beam applying unit 40 and a loading/unloading position, horizontally spaced from the processing position, where the workpiece 1 is loaded onto and unloaded from the holding table 30.

The moving unit assembly 50 operates to move the holding table 30 and the focused spot 411 of the laser beam 41 applied by the laser beam applying unit 40 relatively to each other along the X-axis and the Y-axis and about the central axis parallel to the Z-axis. As described above, the X-axis and the Y-axis extend perpendicularly to each other and horizontally parallel to the holding surface 31, and the Z-axis extends vertically and perpendicularly to the X-axis and the Y-axis.

As described above, the moving unit assembly 50 includes the X-axis moving unit 51 as a processing feed unit for moving the holding table 30 along the X-axis, the Y-axis moving unit 52 as an indexing feed unit for moving the holding table 30 along the Y-axis, and the turning unit 53 for turning the holding table 30 about the central axis parallel to the Z-axis. The moving unit assembly 50 further includes a Z-axis moving unit 54 as a feed unit for moving the focused spot 411 of the laser beam 41 of the laser beam applying unit 40 along the Z-axis.

Specifically, the Y-axis moving unit 52 as the indexing feed unit moves the holding table 30 and the focused spot 411 of the laser beam 41 of the laser beam applying unit 40 relatively to each other along the Y-axis. According to the first embodiment, the Y-axis moving unit 52 is mounted on a foundation base 21 of the laser processing apparatus 20. The X-axis moving unit 51 is mounted on a first movable plate 24 that is movably supported on the Y-axis moving unit 52 for movement along the Y-axis.

The X-axis moving unit 51 as the processing feed unit moves the holding table 30 and the focused spot 411 of the laser beam 41 relatively to each other along the X-axis. The turning unit 53 is mounted on a second movable plate 25 that is movably supported on the X-axis moving unit 51 on the first movable plate 24 for movement along the X-axis. The second movable plate 25 supports the turning unit 53 and the holding table 30 thereon. The turning unit 53 supports the holding table 30 thereon.

The Z-axis moving unit 54 as the feed unit moves the holding table 30 and the focused spot 411 of the laser beam 41 of the laser beam applying unit 40 relatively to each other along the Z-axis. The Z-axis moving unit 54 is mounted on an upstanding wall 22 erected on the foundation base 21. The Z-axis moving unit 54 supports a support arm 23 thereon for movement along the Z-axis. The support arm 23 supports some components of the laser beam applying unit 40 on its distal end remote from the upstanding wall 22.

The X-axis moving unit 51 includes a known ball screw rotatable about its central axis for moving the second movable plate 25 along the X-axis when rotated, a known stepping motor for rotating the ball screw about its central axis, and a pair of known guide rails on which the second movable plate 25 is movably supported for movement along the X-axis. The Y-axis moving unit 52 similarly includes a known ball screw rotatable about its central axis for moving the first movable plate 24 along the Y-axis when rotated, a known stepping motor for rotating the ball screw about its central axis, and a pair of known guide rails on which the first movable plate 24 is movably supported for movement along the Y-axis. Likewise, the Z-axis moving unit 54 includes a known ball screw rotatable about its central axis for moving the support arm 23 along the Z-axis when rotated, a known stepping motor for rotating the ball screw about its central axis, and a pair of known guide rails on which the support arm 23 is movably supported for movement along the Z-axis. The turning unit 53 includes an electric motor, not depicted, for turning the holding table 30 about its central axis.

The laser processing apparatus 20 further includes an X-axis position detecting unit, not depicted, for detecting the position of the holding table 30 along the X-axis, a Y-axis position detecting unit, not depicted, for detecting the position of the holding table 30 along the Y-axis, and a Z-axis position detecting unit, not depicted, for detecting the position of a condensing lens, not depicted, of the laser beam applying unit 40 along the Z-axis. Each of the position detecting units outputs the detected position to the controller 45. According to the first embodiment, the positions of the holding table 30 of the laser processing apparatus 20 along the X-axis and the Y-axis and the position of the condensing lens of the laser beam applying unit 40 along the Z-axis are defined on the basis of their distances from respective predetermined reference positions, not depicted, along the X-axis, the Y-axis, and the Z-axis.

The laser beam applying unit 40 refers to laser beam applying means for converging the pulsed laser beam 41 through the condensing lens and applying the converged pulsed laser beam 41 to the workpiece 1 held on the holding surface 31 of the holding table 30. According to the first embodiment, as illustrated in FIG. 4, some components of the laser beam applying unit 40 are supported on the distal end of the support arm 23 that is movably supported on upstanding wall 22 erected on the foundation base 21 by the Z-axis moving unit 54.

When the laser beam applying unit 40 is energized, it generates and applies the pulsed laser beam 41 to the workpiece 1 held on the holding surface 31 of the holding table 30 to ablate the workpiece 1.

When the image capturing unit 43 is energized, it captures an image of the workpiece 1 on the holding table 30. The image capturing unit 43 includes an image capturing device such as a CCD image sensor or a CMOS image sensor, for example. According to the first embodiment, the image capturing unit 43 is disposed on the distal end of the support arm 23 and includes an objective lens, not depicted, disposed in juxtaposed relation to the condensing lens of the laser beam applying unit 40 along the X-axis.

The image capturing unit 43 acquires an image captured by the image capturing device and outputs the acquired image to the controller 45. The image capturing unit 43 also acquires an image captured of the workpiece 1 on the holding surface 31 of the holding table 30 by the image capturing device for use in an alignment process for positioning the workpiece 1 and the laser beam applying unit 40 with respect to each other.

When the controller 45 is operated, it controls the various components, referred to above, of the laser processing apparatus 20 to enable the laser processing apparatus 20 to process the workpiece 1 with the laser beam 41. The controller 45 is implemented by a computer, not depicted, including a processing device that has a microprocessor such as a central processing unit (CPU), a storage device that has a memory such as a read only memory (ROM) or a random access memory (RAM), and an input/output interface device. The processing device of the controller 45 performs functions of the controller 45 by carrying out processing sequences according to computer programs stored in the storage device and generating and outputting control signals for controlling the laser processing apparatus 20 via the input/output interface device to the components of the laser processing apparatus 20.

The laser processing apparatus 20 also includes a display unit as display means including a liquid crystal display device for displaying states of processing operations of the laser processing apparatus 20 and images captured by the image capturing unit 43, and an input unit as input means that can be used by an operator to enter processing conditions and other signals and data. The display unit and the input unit are electrically connected to the controller 45. According to the first embodiment, the input unit is implemented as a touch panel incorporated in the display unit.

### Alignment Step

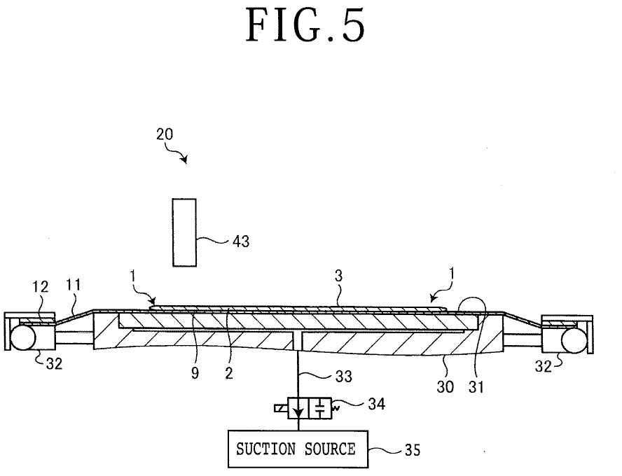

FIG. 5 schematically illustrates, in side elevation, partly in cross section, alignment step 102 of the workpiece processing method illustrated in FIG. 2. Alignment step 102 is a step of performing an alignment process for positioning the laser beam applying unit 40 of the laser processing apparatus 20 and the projected dicing lines 6 of the workpiece 1 with respect to each other. According to the first embodiment, in alignment step 102, the controller 45 of the laser processing apparatus 20 receives and registers processing conditions for first and second processing steps 103 and 104 that have been entered by the operator, and the workpiece 1 is placed on the holding surface 31 of the holding table 30 that has been positioned in the loading/unloading position. When the controller 45 accepts a command for starting a laser processing operation from the operator, the controller 45 actuates the suction source 35 to generate a negative pressure and opens the on/off valve 34 to transmit the generated negative pressure from the suction source 35 to the holding surface 31, thereby holding the workpiece 1 under suction on the holding surface 31 with the vinyl chloride tape 11 interposed therebetween. At the same time, the controller 45 controls the clamps 32 to grip the annular frame 12.

According to the first embodiment, in alignment step 102, as illustrated in FIG. 4, the controller 45 then controls the moving unit assembly 50 to move the holding table 30 to the processing position and to orient the second projected dicing lines 5 of the workpiece 1 on the holding table 30 parallel to the X-axis. The controller 45 also controls the image capturing unit 43 to capture an image of the workpiece 1 on the holding table 30, as illustrated in FIG. 5. The controller 45 then detects the positions of the second projected dicing lines 5 by performing pattern matching between the image captured by the image capturing unit 43 and a predetermined target pattern included in the registered processing conditions, and stores the detected positions of the second projected dicing lines 5.

According to the first embodiment, in alignment step 102, the controller 45 then controls the moving unit assembly 50 to move the holding table 30 to the processing position and to orient the first projected dicing lines 4 of the workpiece 1 on the holding table 30 parallel to the X-axis. The controller 45 also controls the image capturing unit 43 to capture an image of the workpiece 1 on the holding table 30. The controller 45 then detects the positions of the first projected dicing lines 4 by performing pattern matching between the image captured by the image capturing unit 43 and a predetermined target pattern included in the registered processing conditions, and stores the detected positions of the first projected dicing lines 4. The controller 45 then controls the moving unit assembly 50 to orient the first projected dicing lines 4 parallel to or along the X-axis and specifies a position where the laser beam 41 is to be applied to the workpiece 1, on the basis of the detected positions, thereby performing the alignment process.

### First Processing Step

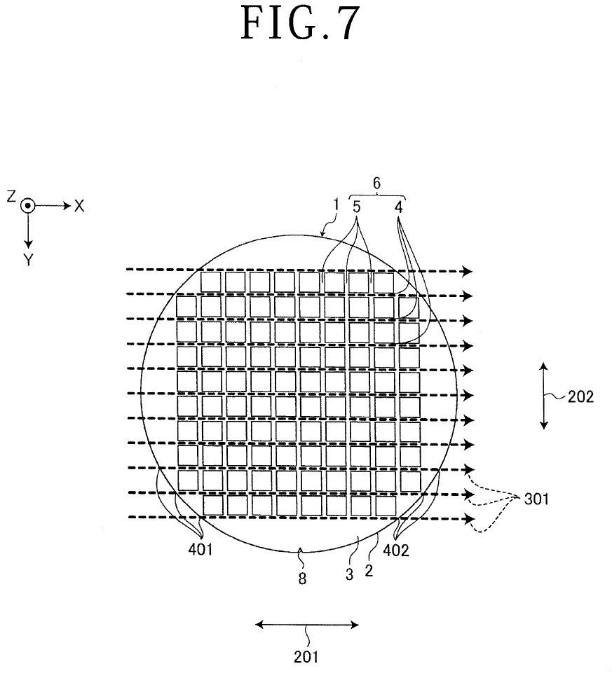

FIG. 6 schematically illustrates, in side elevation, partly in cross section, first processing step 103 and second processing step 104 of the workpiece processing method illustrated in FIG. 2. FIG. 7 schematically illustrates, in plan, a direction in which the laser beam 41 is moved relatively to the workpiece 1 in first processing step 103 of workpiece processing method illustrated in FIG. 2. FIG. 8 schematically illustrates, in plan, the workpiece 1 after first processing step 103 of workpiece processing method illustrated in FIG. 2.

First processing step 103 is a step of applying the laser beam 41 to the workpiece 1 along the first projected dicing lines 4 to divide the workpiece 1 into a plurality of strips 13. Specifically, according to the first embodiment, in first processing step 103, the controller 45 sets the focused spot 411 of the laser beam 41 on the face side 3 of the substrate 2 on the basis of the processing conditions. As illustrated in FIG. 6, the controller 45 then applies the pulsed laser beam 41 to the face side 3 of the substrate 2 along the aligned first projected dicing line 4 while controlling the moving unit assembly 50 to move the holding table 30 and the laser beam applying unit 40 relatively to each other along the first projected dicing line 4, processing the workpiece 1 along the first projected dicing line 4 by way of laser ablation.

According to the first embodiment, in first processing step 103, as illustrated in FIG. 7, the laser beam applying unit 40 starts applying the laser beam 41 to the workpiece 1 at one end 401 of the aligned first projected dicing line 4 that is located at an end portion, i.e., a lower end portion in FIG. 7, of the workpiece 1 along the Y-axis. The moving unit assembly 50 moves the holding table 30 along the X-axis relatively to the laser beam applying unit 40 to move the laser beam 41 from the one end 401 toward another end 402 of the first projected dicing line 4, as indicated by a broken-line arrow 301. When the laser beam 41 has reached the other end 402 of the first projected dicing line 4, the laser beam applying unit 40 stops applying the laser beam 41 to the workpiece 1 at the other end 402.

According to the first embodiment, in first processing step 103, after having applied the laser beam 41 to the workpiece 1 along the full length of the first projected dicing line 4 at the end portion of the workpiece 1 along the Y-axis, the moving unit assembly 50 moves the holding table 30 and the laser beam applying unit 40 along the X-axis and the Y-axis relatively to each other to position the laser beam applying unit 40 above the one end 401 of a first projected dicing line 4 next along the Y-axis to the first projected dicing line 4 that has already been irradiated with the laser beam 41. Then, the laser beam applying unit 40 starts applying the laser beam 41 to the workpiece 1 at the one end 401 of the next first projected dicing line 4, and the moving unit assembly 50 moves the holding table 30 along the X-axis relatively to the laser beam applying unit 40 to move the laser beam 41 from the one end 401 toward the other end 402 of the next first projected dicing line 4, as indicated by the broken-line arrow 301. When the laser beam 41 has reached the other end 402 of the next first projected dicing line 4, the laser beam applying unit 40 stops applying the laser beam 41 to the workpiece 1 at the other end 402. Thereafter, the laser beam applying unit 40 applies the laser beam 41 to the workpiece 1 along a further next first projected dicing line 4 from the one end 401 to the other end 402 thereof in the same manner as described above.

According to the first embodiment, in first processing step 103, the laser processing apparatus 20 thus applies the laser beam 41 to the workpiece 1 successively along the first projected dicing lines 4 all the way from the ends 401 to the other ends 402 thereof, thereby dividing the workpiece 1 on the holding table 30 into a plurality of strips 13 extending along the X-axis, as illustrated in FIG. 8. Since the laser beam 41 is applied to the workpiece 1 along the first projected dicing lines 4 all the way from the ends 401 to the other ends 402 thereof in first processing step 103, all of the strips 13 that have been cut from the workpiece 1 are caused to shift back toward the ends 401 from the position prior to first processing step 103 along the direction in which the laser beam 41 is moved relatively to the workpiece 1.

### Second Processing Step

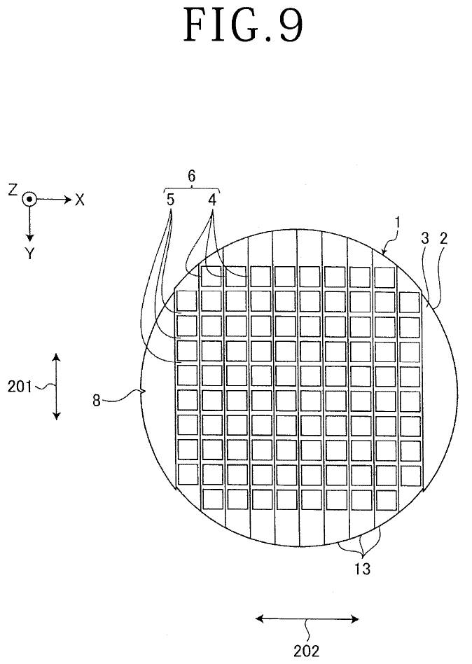

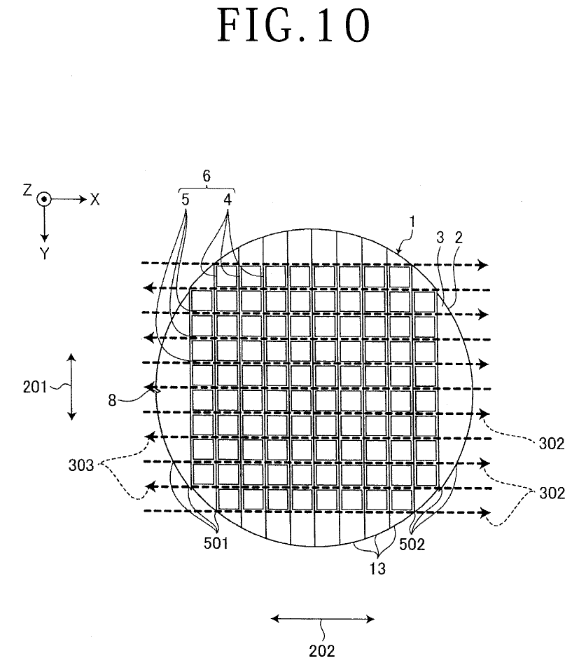

FIG. 9 schematically illustrates, in plan, the workpiece 1 before the laser beam 41 is applied thereto in second processing step 104 of the workpiece processing method illustrated in FIG. 2. FIG. 10 schematically illustrates, in plan, directions in which the laser beam 41 is moved relatively to the workpiece 1 in second processing step 104 of the workpiece processing method illustrated in FIG. 2.

Second processing step 104 is a step, after first processing step 103, of applying the laser beam 41 to the workpiece 1 along the second projected dicing lines 5 to divide the workpiece 1, i.e., the strips 13, into a plurality of chips 10. According to the first embodiment, in second processing step 104, the controller 45 controls the moving unit assembly 50 to turn the holding table 30 through 90 degrees about its central axis and to orient the second projected dicing lines 5 of the workpiece 1 on the holding table 30 along the X-axis, and specifies a position where the laser beam 41 is to be applied to the workpiece 1, on the basis of the positions of the second projected dicing lines 5 detected in alignment step 102.

According to the first embodiment, in second processing step 104, the controller 45 sets the focused spot 411 of the laser beam 41 on the face side 3 of the substrate 2 on the basis of the processing conditions. The controller 45 then applies the pulsed laser beam 41 to the face side 3 of the substrate 2 along the aligned second projected dicing line 5 while controlling the moving unit assembly 50 to move the holding table 30 and the laser beam applying unit 40 relatively to each other along the second projected dicing line 5, processing the workpiece 1 along the second projected dicing line 5 by way of laser ablation.

According to the first embodiment, in second processing step 104, as illustrated in FIG. 10, the laser beam applying unit 40 starts applying the laser beam 41 to the workpiece 1 at one end 501 of the aligned second projected dicing line 5 that is located at an end portion, i.e., a lower end portion in FIG. 10, of the workpiece 1 along the Y-axis. The moving unit assembly 50 moves the holding table 30 along the X-axis relatively to the laser beam applying unit 40 to move the laser beam 41 from the one end 501 toward another end 502 of the second projected dicing line 5, as indicated by a broken-line arrow 302. When the laser beam 41 has reached the other end 502 of the second projected dicing line 5, the laser beam applying unit 40 stops applying the laser beam 41 to the workpiece 1 at the other end 502.

According to the first embodiment, in second processing step 104, after having applied the laser beam 41 to the workpiece 1 along the full length of the second projected dicing line 5 at the end portion of the workpiece 1 along the Y-axis, the moving unit assembly 50 moves the holding table 30 and the laser beam applying unit 40 along the X-axis and the Y-axis relatively to each other to position the laser beam applying unit 40 above the other end 502 of a second projected dicing line 5 next along the Y-axis to the second projected dicing line 5 that has already been irradiated with the laser beam 41. Then, the laser beam applying unit 40 starts applying the laser beam 41 to the workpiece 1 at the other end 502 of the next second projected dicing line 5, and the moving unit assembly 50 moves the holding table 30 along the X-axis relatively to the laser beam applying unit 40 to move the laser beam 41 from the other end 502 toward the one end 501 of the next second projected dicing line 5, as indicated by a broken-line arrow 303. When the laser beam 41 has reached the one end 501 of the next second projected dicing line 5, the laser beam applying unit 40 stops applying the laser beam 41 to the workpiece 1 the one end 501. Thereafter, the laser beam applying unit 40 applies the laser beam 41 to the workpiece 1 along a further next second projected dicing line 5 from the one end 501 to the other end 502 thereof in the same manner as described above.

According to the first embodiment, in second processing step 104, the laser processing apparatus 20 thus applies the laser beam 41 to the workpiece 1 successively all the way along the second projected dicing lines 5, thereby dividing the workpiece 1, i.e., the strips 13, on the holding table 30 into a plurality of chips 10. In addition, after the laser beam applying unit 40 has applied the laser beam 41 to the workpiece 1 fully along a second projected dicing line 5 while the moving unit assembly 50 has been moving the holding table 30 in one direction along the X-axis, the laser beam applying unit 40 applies the laser beam 41 to the workpiece 1 fully along a next second projected dicing line 5 while the moving unit assembly 50 is moving the holding table 30 in the opposite direction along the X-axis. Specifically, in second processing step 104, after the laser beam 41 has been applied to the workpiece 1 along a second projected dicing line 5 from one end 501 to the other end 502, the laser beam 41 is applied to the workpiece 1 along a next second projected dicing line 5 from the other end 502 to the one end 501. The above cycle of applying the laser beam 41 to the workpiece 1 successively along two adjacent second projected dicing lines 5 alternately in opposite directions therealong is repeated until the laser beam 41 is applied to the workpiece 1 along all of the second projected dicing lines 5.

According to the first embodiment, in the workpiece processing method, as described above, the laser beam 41 is applied to the workpiece 1 only once, i.e., only in one pass, along each of the first and second projected dicing lines 4 and 5, dividing the workpiece 1 into individual chips 10. The individual chips 10 thus fabricated from the workpiece 1 will then be picked up from the vinyl chloride tape 11.

As a result of the study devoted to the workpiece processing method according to the present invention, the inventor of the present invention has found that when the laser beam 41 is applied to the workpiece 1 to divide it into the strips 13 along the first projected dicing lines 4 in order to fabricate the smaller square, i.e., rectangular, chips 10 having the size of 0.5 mm×0.5 mm, the strips 13 as they are severed from the workpiece 1 are caused to shift back along the direction in which the laser beam 41 is moved relatively to the workpiece 1. The invention also has discovered that the strips 13 are caused to shift back by approximately uniform distances irrespective of the length of the strips 13.

In the workpiece processing method according to the first embodiment described above, in first processing step 103 of dividing the workpiece 1 into the strips 13, inasmuch as the laser beam 41 is applied to the workpiece 1 along all of the first projected dicing lines 4 from their ends 401 to their other ends 402, the strips 13 are caused to shift positionally in one direction and remain in the shifted positions after first processing step 103.

In the workpiece processing method according to the first embodiment, consequently, the laser beam 41 can subsequently be applied to the workpiece 1 along the second projected dicing lines 5 without being applied to the devices 7 in second processing step 104. As a consequence, the workpiece processing method according to the first embodiment is advantageous in that it is effective to restrain the devices 7 from being damaged by the laser beam 41 that is applied to the workpiece 1 to divide it into the chips 10.

### Second Embodiment

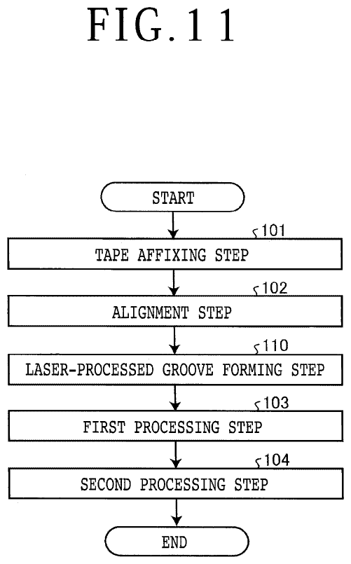

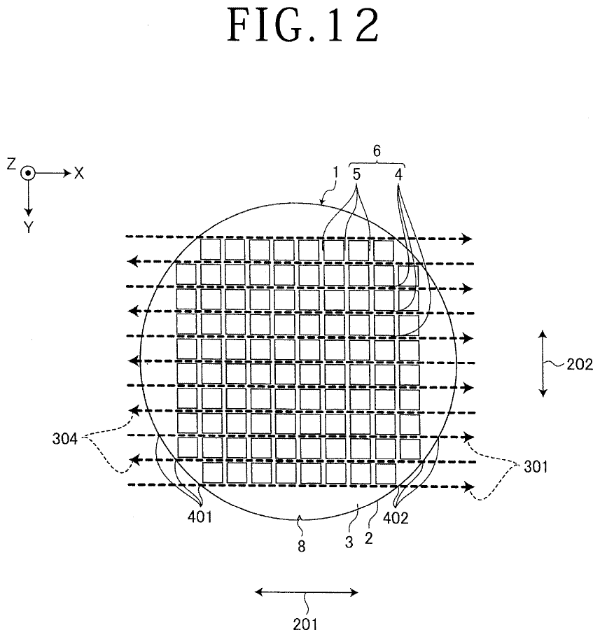

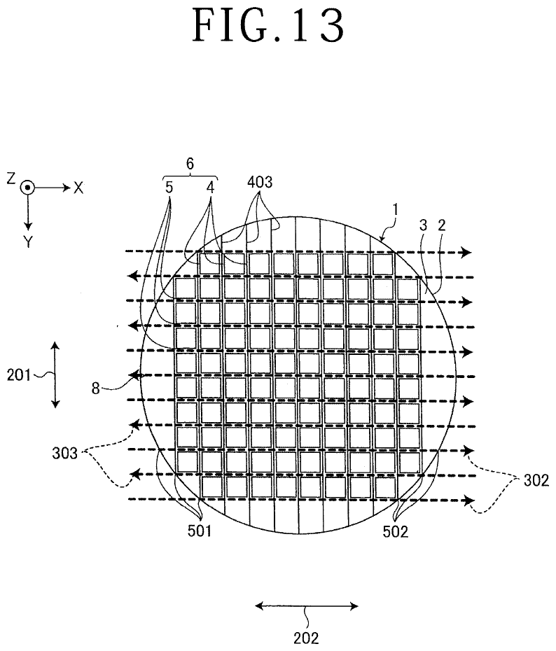

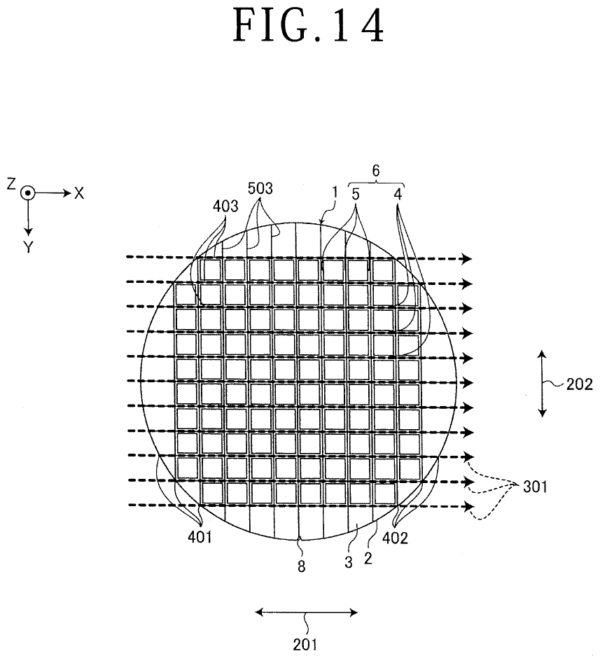

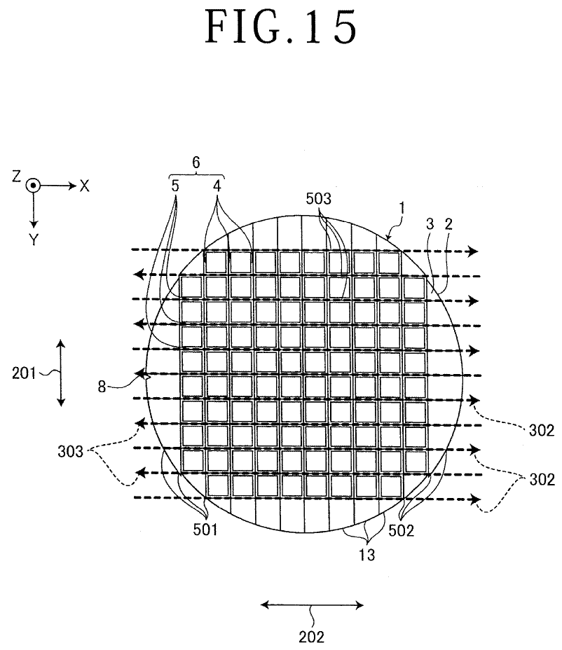

A workpiece processing method according to a second embodiment of the present invention will be described below with reference to the drawings. FIG. 11 is a flowchart of the sequence of the workpiece processing method according to the second embodiment. FIG. 12 schematically illustrates, in plan, directions in which a laser beam moves relatively to first projected dicing lines on a workpiece in a laser-processed groove forming step of the workpiece processing method illustrated in FIG. 11. FIG. 13 schematically illustrates, in plan, directions in which the laser beam moves relatively to second projected dicing lines on the workpiece in the laser-processed groove forming step of the workpiece processing method illustrated in FIG. 11. FIG. 14 schematically illustrates, in plan, a direction in which the laser beam moves relatively to the workpiece in a first processing step of the workpiece processing method illustrated in FIG. 11. FIG. 15 schematically illustrates, in plan, directions in which the laser beam moves relatively to the workpiece in a second processing step of the workpiece processing method illustrated in FIG. 11. Those parts illustrated in FIGS. 11 through 15 that are identical to those illustrated in FIGS. 7 through 10 according to the first embodiment are denoted by identical reference characters and will be omitted from detailed description.

The workpiece processing method according to the second embodiment is essentially identical to the workpiece processing method according to the first embodiment except that the laser beam 41 is applied to the workpiece 1 a plurality of times, e.g., three times or in three passes according to the second embodiment, along each of the first and second projected dicing lines 4 and 5 to divide the workpiece 1 into individual chips 10 and that the workpiece processing method according to the second embodiment additionally includes laser-processed groove forming step 110 (see FIG. 11). According to the second embodiment, the workpiece 1 has a thickness of 270 μm and is ablated thicknesswise to a depth of 90 μm by the laser beam 41 when it is applied once, i.e., in one pass, to the workpiece 1.

Laser-processed groove forming step 110 is a step, prior to first processing step 103, of applying the laser beam 41 to the workpiece 1 along each of the first projected dicing lines 4 to form a first laser-processed groove 403 (see FIG. 13) in the workpiece 1 and thereafter applying the laser beam 41 to the workpiece 1 along each of the second projected dicing lines 5 to form a second laser-processed groove 503 (see FIG. 14). According to the second embodiment, in laser-processed groove forming step 110, the controller 45 sets the focused spot 411 of the laser beam 41 on the face side 3 of the substrate 2 on the basis of the processing conditions. Then, while controlling the moving unit assembly 50 to move the holding table 30 and the laser beam applying unit 40 relatively to each other along one of the first projected dicing lines 4, the controller 45 controls the laser beam applying unit 40 to apply the pulsed laser beam 41 to the face side 3 of the substrate 2 of the workpiece 1 along the first projected dicing line 4, processing the workpiece 1 along the first projected dicing line 4 by way of laser ablation.

According to the second embodiment, in laser-processed groove forming step 110, as illustrated in FIG. 12, the laser beam applying unit 40 starts applying the laser beam 41 to the workpiece 1 at one end 401 of the first projected dicing line 4 that is located at an end portion, i.e., a lower end portion in FIG. 12, of the workpiece 1 along the Y-axis. The moving unit assembly 50 moves the holding table 30 along the X-axis relatively to the laser beam applying unit 40 to move the laser beam 41 from the end 401 toward the other end 402 of the first projected dicing line 4, as indicated by the broken-line arrow 301. When the laser beam 41 has reached the other end 402 of the first projected dicing line 4, the laser beam applying unit 40 stops applying the laser beam 41 to the workpiece 1 at the other end 402.

According to the second embodiment, in laser-processed groove forming step 110, after having applied the laser beam 41 to the workpiece 1 along the full length of the first projected dicing line 4 at the end portion of the workpiece 1 along the Y-axis, the moving unit assembly 50 moves the holding table 30 and the laser beam applying unit 40 along the X-axis and the Y-axis relatively to each other to position the laser beam applying unit 40 above the other end 402 of a first projected dicing line 4 next along the Y-axis to the first projected dicing line 4 that has already been irradiated with the laser beam 41. Then, the laser beam applying unit 40 starts applying the laser beam 41 to the workpiece 1 at the other end 402 of the next first projected dicing line 4, and the moving unit assembly 50 moves the holding table 30 along the X-axis relatively to the laser beam applying unit 40 to move the laser beam 41 from the other end 402 toward the one end 401 of the next first projected dicing line 4, as indicated by a broken-line arrow 304. When the laser beam 41 has reached the one end 401 of the next first projected dicing line 4, the laser beam applying unit 40 stops applying the laser beam 41 to the workpiece 1 at the one end 401.

According to the second embodiment, in laser-processed groove forming step 110, the laser beam applying unit 40 applies the laser beam 41 to the workpiece 1 along a further next first projected dicing line 4 from the end 401 to the other end 402 thereof in the same manner as described above. In laser-processed groove forming step 110, the laser processing apparatus 20 thus applies the laser beam 41 to the workpiece 1 successively along the first projected dicing lines 4 arrayed from an end portion of the workpiece 1 along the Y-axis toward another end portion thereof. Specifically, when the laser beam 41 is applied to the workpiece 1 along a set of alternate first projected dicing lines 4, the holding table 30 is moved relatively to the laser beam applying unit 40 in one direction along the X-axis. When the laser beam 41 is applied to the workpiece 1 along another set of alternate first projected dicing lines 4, the holding table 30 is moved relatively to the laser beam applying unit 40 in the opposite direction along the X-axis. In this fashion, the laser processing apparatus 20 applies the laser beam 41 to the workpiece 1 along all of the first projected dicing lines 4, forming first laser-processed grooves 403 in the workpiece 1 along the first projected dicing lines 4.

In laser-processed groove forming step 110, then, the controller 45 controls the moving unit assembly 50 to turn the holding table 30 through 90 degrees about its central axis and to orient the second projected dicing lines 5 of the workpiece 1 on the holding table 30 along the X-axis, and specifies a position where the laser beam 41 is to be applied to the workpiece 1, on the basis of the positions of the second projected dicing lines 5 detected in alignment step 102. Then, the controller 45 sets the focused spot 411 of the laser beam 41 on the face side 3 of the substrate 2 on the basis of the processing conditions. The controller 45 then applies the pulsed laser beam 41 to the face side 3 of the substrate 2 along the aligned second projected dicing line 5 while controlling the moving unit assembly 50 to move the holding table 30 and the laser beam applying unit 40 relatively to each other along the second projected dicing line 5, processing the workpiece 1 along the second projected dicing line 5 by way of laser ablation.

According to the second embodiment, in laser-processed groove forming step 110, the laser beam applying unit 40 starts applying the laser beam 41 to the workpiece 1 at one end 501 of the aligned second projected dicing line 5 that is located at an end portion, i.e., a lower end portion in FIG. 13, of the workpiece 1 along the Y-axis. The moving unit assembly 50 moves the holding table 30 along the X-axis relatively to the laser beam applying unit 40 to move the laser beam 41 from the one end 501 toward another end 502 of the second projected dicing line 5, as indicated by the broken-line arrow 302. When the laser beam 41 has reached the other end 502 of the second projected dicing line 5, the laser beam applying unit 40 stops applying the laser beam 41 to the workpiece 1 at the other end 502.

According to the second embodiment, in laser-processed groove forming step 110, after having applied the laser beam 41 to the workpiece 1 along the full length of the second projected dicing line 5 at the end portion of the workpiece 1 along the Y-axis, the moving unit assembly 50 moves the holding table 30 and the laser beam applying unit 40 along the X-axis and the Y-axis relatively to each other to position the laser beam applying unit 40 above the other end 502 of a second projected dicing line 5 next along the Y-axis to the second projected dicing line 5 that has already been irradiated with the laser beam 41. Then, the laser beam applying unit 40 starts applying the laser beam 41 to the workpiece 1 at the other end 502 of the next second projected dicing line 5, and the moving unit assembly 50 moves the holding table 30 along the X-axis relatively to the laser beam applying unit 40 to move the laser beam 41 from the other end 502 toward the one end 501 of the next second projected dicing line 5, as indicated by the broken-line arrow 303. When the laser beam 41 has reached the one end 501 of the next second projected dicing line 5, the laser beam applying unit 40 stops applying the laser beam 41 to the workpiece 1 at the one end 501.

According to the second embodiment, in laser-processed groove forming step 110, the laser beam applying unit 40 applies the laser beam 41 to the workpiece 1 along a further next first projected dicing line 4 from the one end 501 to the other end 502 thereof in the same manner as described above. In laser-processed groove forming step 110, the laser processing apparatus 20 thus applies the laser beam 41 to the workpiece 1 successively along the first projected dicing lines 4 arrayed from an end portion of the workpiece 1 along the Y-axis toward another end portion thereof. Specifically, when the laser beam 41 is applied to the workpiece 1 along a set of alternate first projected dicing lines 4, the holding table 30 is moved relatively to the laser beam applying unit 40 in one direction along the X-axis. When the laser beam 41 is applied to the workpiece 1 along another set of alternate first projected dicing lines 4, the holding table 30 is moved relatively to the laser beam applying unit 40 in the opposite direction along the X-axis. In this fashion, the laser processing apparatus 20 applies the laser beam 41 to the workpiece 1 along all of the second projected dicing lines 5, forming second laser-processed grooves 503 in the workpiece 1 along the second projected dicing lines 5.

Thereafter, according to the second embodiment, in laser-processed groove forming step 110, the controller 45 controls the moving unit assembly 50 to turn the holding table 30 about its central axis to align the first projected dicing lines 4 of the workpiece 1 on the holding table 30 with the X-axis and to position the focused spot 411 of the laser beam 41 on the bottom of the first laser-processed groove 403 along one of the aligned first projected dicing lines 4. The controller 45 controls the laser beam applying unit 40 to apply the laser beam 41 to the workpiece 1 along the first projected dicing line 4, forming a first laser-processed groove 403 in the bottom of the first laser-processed groove 403. The controller 45 similarly controls the laser beam applying unit 40 to apply the laser beam 41 to the workpiece 1 once along all of the first projected dicing lines 4, forming first laser-processed grooves 403 in the bottoms of all of the first laser-processed grooves 403 defined in the workpiece 1 along all of the first projected dicing lines 4. Likewise, the controller 45 controls the moving unit assembly 50 to turn the holding table 30 about its central axis to align the second projected dicing lines 5 of the workpiece 1 on the holding table 30 with the X-axis and to position the focused spot 411 of the laser beam 41 on the bottom of the second laser-processed groove 503 along one of the aligned second projected dicing lines 5. The controller 45 controls the laser beam applying unit 40 to apply the laser beam 41 to the workpiece 1 along the second projected dicing line 5, forming a second laser-processed groove 503 in the bottom of the second laser-processed groove 503. The controller 45 similarly controls the laser beam applying unit 40 to apply the laser beam 41 to the workpiece 1 once along all of the second projected dicing lines 5, forming second laser-processed grooves 503 in the bottoms of all of the second laser-processed grooves 503 defined in the workpiece 1 along all of the second projected dicing lines 5.

As described above, according to the second embodiment, in laser-processed groove forming step 110, after having applied the laser beam 41 to the workpiece 1 along a first projected dicing line 4 or a second projected dicing line 5 from the one end 401 or 501 toward the other end 402 or 502 thereof, the laser processing apparatus 20 repeats the cycle of applying the laser beam 41 to the workpiece 1 along a first projected dicing line 4 or a second projected dicing line 5 next to the first projected dicing line 4 or the second projected dicing line 5 that have already been irradiated with the laser beam 41, from the other end 402 or 502 toward the one end 401 or 501 thereof until the laser-processed groove 403 or 503 is formed a plurality of times in the workpiece 1 along all of the first projected dicing lines 4 or the second projected dicing lines 5. After having formed the laser-processed grooves 403 and 503 a plurality of times, e.g., twice according to the second embodiment, in the workpiece 1 along all of the first and second projected dicing lines 4 and 5, the controller 45 controls the moving unit assembly 50 to turn the holding table 30 to orient the first projected dicing lines 4 along the X-axis.

According to the second embodiment, in first processing step 103, the laser processing apparatus 20 sets the focused spot 411 of the laser beam 41 on the bottoms of the first laser-processed grooves 403 and applies the laser beam 41 to the workpiece 1 along the first projected dicing lines 4, dividing the workpiece 1 into a plurality of strips 13, as illustrated in FIG. 14, in the same manner as with the first embodiment. According to the second embodiment, in second processing step 104, the laser processing apparatus 20 sets the focused spot 411 of the laser beam 41 on the bottoms of the second laser-processed grooves 503 and applies the laser beam 41 to the workpiece 1 along the second projected dicing lines 5, dividing the workpiece 1, i.e., the strips 13, into individual chips 10, as illustrated in FIG. 15, in the same manner as with the first embodiment.

In the workpiece processing method according to the second embodiment, since the laser beam 41 is applied to the workpiece 1 along all of the first projected dicing lines 4 from the one ends 401 toward the other ends 402 thereof in first processing step 103 of dividing the workpiece 1 into the strips 13, the strips 13 shift in position along one direction after they have been produced from the workpiece 1 in first processing step 103. As a consequence, the workpiece processing method according to the second embodiment is advantageous in that the laser beam 41 can subsequently be applied to the workpiece 1 along the second projected dicing lines 5 without being applied to the devices 7 and hence the devices 7 are restrained from being damaged in second processing step 104 as with the first embodiment.

### Third Embodiment

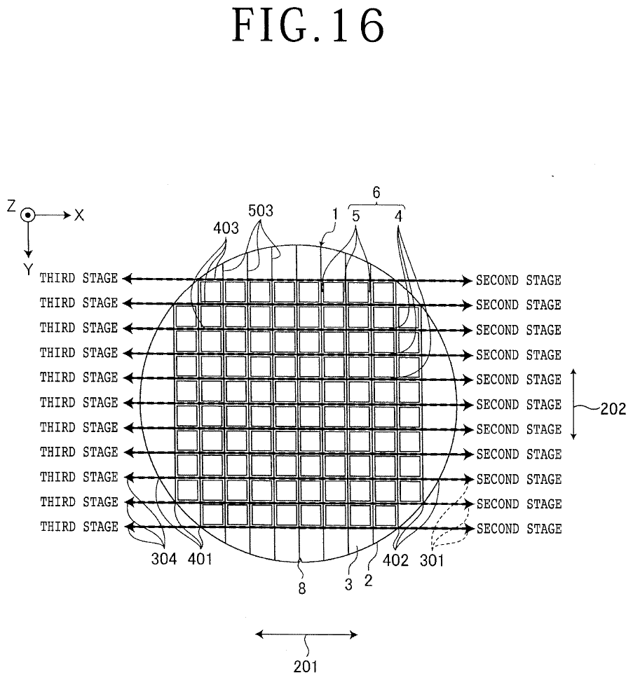

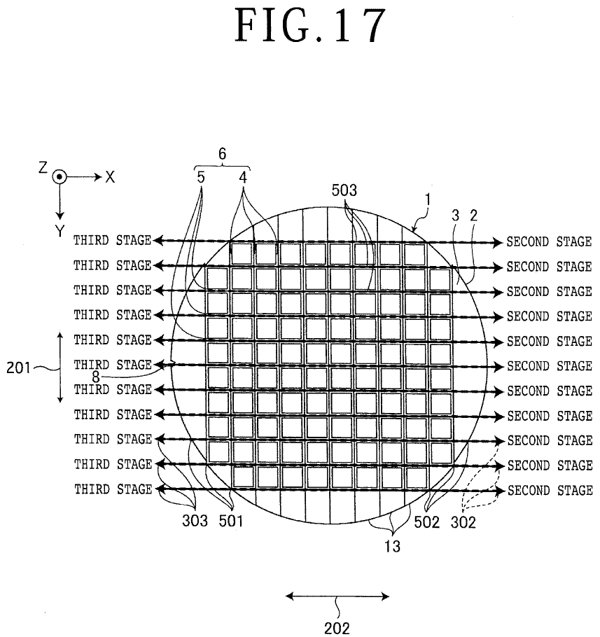

A workpiece processing method according to a third embodiment of the present invention will be described below with reference to the drawings. FIG. 16 schematically illustrates, in plan, directions in which a laser beam moves relatively to first projected dicing lines on a workpiece in a first processing step of the workpiece processing method according to the third embodiment. FIG. 17 schematically illustrates, in plan, directions in which the laser beam moves relatively to second projected dicing lines on the workpiece in a second processing step of the workpiece processing method according to the third embodiment. Those parts illustrated in FIGS. 16 and 17 that are identical to those illustrated in FIGS. 7 through 10 according to the first embodiment are denoted by identical reference characters and will be omitted from detailed description.

The workpiece processing method according to the third embodiment is essentially identical to the workpiece processing method according to the first embodiment except that the laser beam 41 is applied to the workpiece 1 a plurality of times, e.g., three times or in three passes according to the third embodiment, along each of the first and second projected dicing lines 4 and 5 to divide the workpiece 1 into individual chips 10, that the workpiece processing method according to the third embodiment additionally includes laser-processed groove forming step 110 as with the second embodiment, and that processing steps 103 and 104 are different. According to the third embodiment, as with the second embodiment, the workpiece 1 has a thickness of 270 μm and is ablated thicknesswise to a depth of 90 μm by the laser beam 41 when it is applied once, i.e., in one pass, to the workpiece 1.

According to the third embodiment, in laser-processed groove forming step 110, the laser beam 41 is applied to the workpiece 1 only once along all of the first projected dicing lines 4 and only once along all of the second projected dicing lines 5, forming first and second laser-processed grooves 403 and 503 in the workpiece 1 along the first and second projected dicing lines 4 and 5, as with the second embodiment. Furthermore, after having controlled the moving unit assembly 50 to turn the holding table 30 about its central axis to orient the second projected dicing lines 5 along the X-axis, the controller 45 performs the alignment process and performs first processing step 103.

According to the third embodiment, in first processing step 103, the controller 45 sets the focused spot 411 of the laser beam 41 on the bottom of the first laser-processed groove 403 along one of the first projected dicing lines 4 and starts applying the laser beam 41 to the workpiece 1 at one end 401 of the first projected dicing line 4 at an end portion, i.e., a lower end portion in FIG. 16, of the workpiece 1 along the Y-axis. The moving unit assembly 50 moves the holding table 30 along the X-axis relatively to the laser beam applying unit 40 to move the laser beam 41 from the one end 401 toward another end 402 of the first projected dicing line 4, as indicated by the broken-line arrow 301. When the laser beam 41 has reached the other end 402 of the first projected dicing line 4, the laser beam applying unit 40 stops applying the laser beam 41 to the workpiece 1 the other end 402. Then, the moving unit assembly 50 moves the holding table 30 along the X-axis relatively to the laser beam applying unit 40 to move the laser beam 41 from the one end 401 toward another end 402 of the first projected dicing line 4, as indicated by the broken-line arrow 301 in FIG. 16. When the laser beam 41 has reached the other end 402 of the first projected dicing line 4, the laser beam applying unit 40 stops applying the laser beam 41 to the workpiece 1 at the other end 402.

According to the third embodiment, in first processing step 103, after having applied the laser beam 41 to the workpiece 1 along the full length of the first projected dicing line 4 at the end portion of the workpiece 1 along the Y-axis, the moving unit assembly 50 sets the focused spot 411 of the laser beam 41 on the bottom of the first laser-processed groove 403 without moving the holding table 30 and the laser beam applying unit 40 along the Y-axis relatively to each other, and then the laser beam applying unit 40 starts applying the laser beam 41 to the workpiece 1 at the other end 402 of the first projected dicing line 4 that has already been irradiated with the laser beam 41. Thereafter, the moving unit assembly 50 moves the holding table 30 along the X-axis relatively to the laser beam applying unit 40 to move the laser beam 41 toward the one end 401 of the first projected dicing line 4, and the laser beam applying unit 40 stops applying the laser beam 41 to the workpiece 1 at the one end 401 of the first projected dicing line 4. In first processing step 103, therefore, the laser processing apparatus 20 applies the laser beam 41 to the workpiece 1 twice, e.g., in two passes according to the third embodiment, along the full length of the first projected dicing line 4 at the end portion of the workpiece 1 along the Y-axis while the holding table 30 is being moved back and forth along the X-axis.

According to the third embodiment, in first processing step 103, after having applied the laser beam 41 to the workpiece 1 twice along the full length of the first projected dicing line 4 at the end portion of the workpiece 1 along the Y-axis, the moving unit assembly 50 moves the holding table 30 and the laser beam applying unit 40 along the Y-axis and the X-axis relatively to each other to position the laser beam applying unit 40 above the one end 401 of a first projected dicing line 4 next along the Y-axis to the first projected dicing line 4 that has already been irradiated with the laser beam 41. The laser processing apparatus 20 then sets the focused spot 411 of the laser beam 41 on the bottom of the first laser-processed groove 403 and starts applying the laser beam 41 to the workpiece 1 at the one end 401 of the next first projected dicing line 4. The moving unit assembly 50 moves the holding table 30 along the X-axis relatively to the laser beam applying unit 40 to move the laser beam 41 from the one end 401 to the other end 402 of the first projected dicing line 4. When the laser beam 41 has reached the other end 402 of the first projected dicing line 4, the laser beam applying unit 40 stops applying the laser beam 41 to the workpiece 1 at the other end 402.

According to the third embodiment, in first processing step 103, the laser processing apparatus 20 sets the focused spot 411 of the laser beam 41 on the bottom of the first laser-processed groove 403 and starts applying the laser beam 41 to the workpiece 1 at the other end 402 of the first projected dicing line 4, and the moving unit assembly 50 moves the holding table 30 along the X-axis relatively to the laser beam applying unit 40 to move the laser beam 41 from the other end 402 toward the one end 401 of the next first projected dicing line 4, as indicated by the broken-line arrow 304. When the laser beam 41 has reached the one end 401 of the next first projected dicing line 4, the laser beam applying unit 40 stops applying the laser beam 41 to the workpiece 1 at the one end 401. Then, the laser processing apparatus 20 applies the laser beam 41 to the workpiece 1 along a further next first projected dicing line 4 from the one end 401 to the other end 402 thereof in the same manner as described above, and thereafter applies the laser beam 41 to the workpiece 1 along the further next first projected dicing line 4 from the other end 402 to the one end 401 thereof.

According to the third embodiment, in first processing step 103, therefore, the laser processing apparatus 20 applies the laser beam 41 to the workpiece 1 twice successively along the first projected dicing lines 4 arrayed from an end portion of the workpiece 1 along the Y-axis toward another end portion thereof while moving the laser beam 41 back and forth along the X-axis, cutting the workpiece 1 on the holding table 30 into a plurality of strips 13 extending along the X-axis. All of the strips 13 thus severed from the workpiece 1 are caused to shift back in position from their positions prior to first processing step 103 toward the other ends 402 of the first projected dicing lines 4 along the direction in which the laser beam 41 is moved relatively to the workpiece 1.

According to the third embodiment, in first processing step 103, therefore, after having applied the laser beam 41 to the workpiece 1 along one of the first projected dicing lines 4 from the one end 401 to the other end 402 thereof and then applied the laser beam 41 to the workpiece 1 along the first projected dicing line 4 from the other end 402 to the one end 401 thereof, the laser processing apparatus 20 applies the laser beam 41 to the workpiece 1 along a next one of the first projected dicing lines 4 in the same manner as described above. Then, the laser processing apparatus 20 repeats the above cycle until the laser beam 41 is applied to the workpiece 1 along all of the first projected dicing lines 4.

According to the third embodiment, in second processing step 104, the controllers 45 controls the moving unit assembly 50 to turn the holding table 30 about its central axis to orient the second projected dicing lines 5 parallel to the X-axis. Then, the laser processing apparatus 20 sets the focused spot 411 of the laser beam 41 on the bottom of the second laser-processed groove 503 along one of the second projected dicing lines 5 and starts applying the laser beam 41 to the workpiece 1 at one end 501 of the second projected dicing line 5 at an end portion of the workpiece 1 along the Y-axis. The moving unit assembly 50 moves the holding table 30 along the X-axis relatively to the laser beam applying unit 40 to move the laser beam 41 from the one end 501 toward the other end 502 of the second projected dicing line 5, as indicated by the broken-line arrow 302 in FIG. 17. When the laser beam 41 has reached the other end 502 of the second projected dicing line 5, the laser beam applying unit 40 stops applying the laser beam 41 to the workpiece 1 at the other end 502.

According to the third embodiment, in second processing step 104, after having applied the laser beam 41 to the workpiece 1 along the full length of the second projected dicing line 5 at the end portion of the workpiece 1 along the Y-axis, the moving unit assembly 50 sets the focused spot 411 of the laser beam 41 on the bottom of the second laser-processed groove 503 without moving the holding table 30 and the laser beam applying unit 40 along the Y-axis relatively to each other, and the laser beam applying unit 40 starts applying the laser beam 41 to the workpiece 1 at the other end 502 of the second projected dicing line 5 that has already been irradiated with the laser beam 41. Then, the moving unit assembly 50 moves the holding table 30 along the X-axis relatively to the laser beam applying unit 40 to move the laser beam 41 from the other end 502 toward the one end 501 of the second projected dicing line 5, as indicated by the broken-line arrow 303 in FIG. 17. When the laser beam 41 has reached the one end 501 of the second projected dicing line 5, the laser beam applying unit 40 stops applying the laser beam 41 to the workpiece 1 at the one end 501. According to the third embodiment, in second processing step 104, therefore, the laser processing apparatus 20 applies the laser beam 41 to the workpiece 1 twice, i.e., in two passes, along the second projected dicing line 5 at the end portion of the workpiece 1 along the Y-axis while moving the holding table 30 back and forth along the X-axis.

According to the third embodiment, in second processing step 104, the laser processing apparatus 20 sets the focused spot 411 of the laser beam 41 on the bottoms of the second laser-processed grooves 503 and applies the laser beam 41 to the workpiece 1 twice along the second projected dicing lines 5 successively arrayed from the end portion of the workpiece 1 along the Y-axis toward the other end portion thereof, dividing the workpiece 1 on the holding table 30, i.e., the strips 13, into individual chips 10, as with first processing step 103. Specifically, in second processing step 104, as with first processing step 103, after having applied the laser beam 41 to the workpiece 1 along one of the second projected dicing lines 5 from the one end 501 to the other end 502 thereof and then applied the laser beam 41 to the workpiece 1 along the second projected dicing line 5 from the other end 502 to the one end 501 thereof, the laser processing apparatus 20 applies the laser beam 41 to the workpiece 1 along a next one of the second projected dicing lines 5 in the same manner as described above. Then, the laser processing apparatus 20 repeats the above cycle until the laser beam 41 is applied to the workpiece 1 along all of the second projected dicing lines 4, dividing the workpiece 1 into individual chips 10.

According to the third embodiment, in second processing step 104, while the laser beam applying unit 40 and the holding table 30 are being moved relatively to each other, the laser beam 41 may be applied to the workpiece 1 along the second projected dicing lines 5 to divide the workpiece 1 into individual chips 10.

In the workpiece processing method according to the third embodiment, since the laser beam 41 is applied to the workpiece 1 along all of the first projected dicing lines 4 from the one ends 401 toward the other ends 402 thereof in first processing step 103 of dividing the workpiece 1 into the strips 13, the strips 13 shift in position along one direction after they have been produced from the workpiece 1 in first processing step 103. As a consequence, the workpiece processing method according to the third embodiment is advantageous in that the laser beam 41 can subsequently be applied to the workpiece 1 along the second projected dicing lines 5 without being applied to the devices 7 and hence the devices 7 are restrained from being damaged in second processing step 104 as with the first embodiment and the second embodiment.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of processing a workpiece to divide the workpiece into a plurality of chips along projected dicing lines established thereon that include a plurality of first projected dicing lines extending in a first direction and a plurality of second projected dicing lines extending in a second direction that traverses the first direction, the method comprising:
a first processing step of applying a laser beam to the workpiece along the first projected dicing lines to divide the workpiece into a plurality of strips; and
after the first processing step, a second processing step of applying the laser beam to the workpiece along the second projected dicing lines to divide the workpiece into a plurality of chips, wherein
the first processing step includes applying the laser beam to the workpiece along the first projected dicing lines from one ends to other ends of the first projected dicing lines, and
the second processing step includes repeating a cycle of applying the laser beam to the workpiece along one of the second projected dicing lines from one end to other end of the one of the second projected dicing lines and thereafter applying the laser beam to the workpiece along a next one of the second projected dicing lines from the other end to the one end of the next one of the second projected dicing lines.

2. The method of processing a workpiece according to claim 1, further comprising:
before the first processing step, a laser-processed groove forming step of applying the laser beam to the workpiece along the first projected dicing lines to form first laser-processed grooves in the workpiece along the first projected dicing lines and thereafter applying the laser beam to the workpiece along the second projected dicing lines to form second laser-processed grooves in the workpiece along the second projected dicing lines, wherein
the laser-processed groove forming step includes repeating a cycle of applying the laser beam to the workpiece along one of the first projected dicing lines or the second projected dicing lines from one end to other end of the one of the first projected dicing lines or the second projected dicing lines and thereafter applying the laser beam to the workpiece along a next one of the first projected dicing lines or the second projected dicing lines from the other end to the one end of the next one of the first projected dicing lines or the second projected dicing lines.

3. A method of processing a workpiece to divide the workpiece into a plurality of chips along projected dicing lines established thereon that include a plurality of first projected dicing lines extending in a first direction and a plurality of second projected dicing lines extending in a second direction that traverses the first direction, the method comprising:
a first processing step of applying a laser beam to the workpiece along the first projected dicing lines to divide the workpiece into a plurality of strips; and,
after the first processing step, a second processing step of applying the laser beam to the workpiece along the second projected dicing lines to divide the workpiece into a plurality of chips, wherein
the first processing step includes repeating a cycle of applying the laser beam to the workpiece along one of the first projected dicing lines from one end to other end of the one of the first projected dicing lines, applying the laser beam to the workpiece along the one of the first projected dicing lines from the other end to the one end of the one of the first projected dicing lines that has been irradiated with the laser beam, and applying the laser beam to the workpiece along a next one of the first projected dicing lines.

4. The method of processing a workpiece according to claim 1, further comprising:
before the first processing step, a tape affixing step of affixing a vinyl chloride tape to the workpiece.
